(19) United States
(12) Patent Application Publication
(10) Pub. No.: US 2025/0098455 A1
(43) Pub. Date: Mar. 20, 2025

(54) DISPLAY DEVICE AND METHOD OF MANUFACTURING THE SAME

(71) Applicant: Samsung Display Co., LTD., Yongin-si (KR)

(72) Inventors: CHOLONG WON, Yongin-si (KR); KIYONG KIM, Yongin-si (KR); HEEJU WOO, Yongin-si (KR); HYUNGBIN CHO, Yongin-si (KR)

(21) Appl. No.: 18/680,281

(22) Filed: May 31, 2024

(30) Foreign Application Priority Data
Sep. 15, 2023 (KR) 10-2023-0123042

(51) Int. Cl. H10K 59/131; H10K 59/123; H10K 102/00

(52) U.S. Cl. CPC H10K 59/131; H10K 59/123; H10K 2102/351

(57) ABSTRACT

A display device includes: a base layer including a display area and a non-display area adjacent to the display area, insulating layers arranged on the base layer, pixels arranged in the display area, pads connected to the pixels, arranged in a first direction, and arranged in the non-display area, and a driving chip connected to the pads. Each of side pads arranged at opposite ends in the first direction among the pads includes: a first conductive pattern; a first insulating pattern including protruding patterns, which protrude in a direction toward the driving chip; and a second insulating pattern disposed on the first insulating pattern.

This application claims priority to Korean Patent Application No. 10-2023-0123042, filed on Sep. 15, 2023, and all the benefits accruing therefrom under 35 U.S.C. § 119, the content of which in its entirety is herein incorporated by reference.

### BACKGROUND

Embodiments of the present disclosure described herein relate to a display device and a method of manufacturing the same, and more particularly to, a display device including a pad having improved bonding reliability and a method of manufacturing the same.

A display device includes a display area that is activated according to an electrical signal and a non-display area adjacent to the display area. The display device may display various images through the display area to provide information to a user, and at the same time, to detect input from the outside. A driving chip may be mounted on a display panel. The driving chip may be connected to the display panel through pads arranged in a non-display area of the display panel.

### SUMMARY

Embodiments of the present disclosure provide a display device having improved bonding reliability between pads and a driving chip, and a method of manufacturing the same.

According to an embodiment, a display device includes: a base layer including a display area and a non-display area adjacent to the display area, insulating layers disposed on the base layer, pixels disposed in the display area, pads connected to the pixels, arranged in a first direction, and disposed in the non-display area, and a driving chip connected to the pads, where each of side pads arranged at opposite ends in the first direction among the pads includes: a first conductive pattern; a first insulating pattern including protruding patterns, which protrudes in a direction toward the driving chip; and a second insulating pattern disposed on the first insulating pattern.

The protruding patterns may have an integral shape in which lower portions of the protruding patterns are connected, a valley recessed in a direction toward the base layer may be defined between the protruding patterns, and the second insulating pattern may overlap the valley in a plan view.

Two valleys recessed in a direction toward the base layer may be defined between the protruding patterns, the second insulating pattern may further include sub-protruding patterns, which protrude in the direction toward the driving chip and overlaps the two valleys in the plan view, respectively, one sub-valley recessed in the direction toward the base layer may be defined between the sub-protruding patterns, and each of the side pads further may include a third insulating pattern disposed on the second insulating pattern and overlapping the sub-valley in the plan view.

Each of the side pads may further include a second conductive pattern that covers the second insulating pattern and a portion of the first insulating pattern exposed from the second insulating pattern.

The second conductive pattern may include first to third conductive layers that are sequentially laminated, and the first conductive layer and the third conductive layer may include titanium, and the second conductive layer may include aluminum.

The first conductive pattern may cover the second insulating pattern and a portion of the first insulating pattern exposed from the second insulating pattern.

The first conductive pattern may cover the second insulating pattern and a portion of the first insulating pattern exposed from the second insulating pattern, and each of the side pads may further include a second conducive pattern that covers the first conductive pattern.

The first insulating pattern may include a positive photoresist (“PR”), and the second insulating pattern may include any one of the positive photoresist (PR) and a negative photoresist (PR).

The first insulating pattern may include a negative photoresist (PR), and the second insulating pattern may include the negative photoresist (PR).

The first insulating pattern and the second insulating pattern may include polymer.

Each of central pads arranged between the side pads among the pads may include a third conductive pattern; an insulating pattern having a convex shape, which protrudes in the direction toward the driving chip; and a fourth conductive pattern that covers the insulating pattern.

The insulating layers may include a barrier layer disposed on the base layer, a buffer layer disposed on the barrier layer, and first to fifth insulating layers arranged on the buffer layer, and each of the third to fifth insulating layers may expose the second insulating layer in the non-display area, and the first conductive pattern may be disposed on the second insulating layer.

The display device may further include data lines that connect the pixels and the pads, is disposed on the first insulating layer, and is covered by the second insulating layer, wherein the first conductive patterns may be arranged in contact holes passing through the second insulating layer and connected to the data lines.

The display device may further include a first connection electrode disposed on the second insulating layer, disposed in a contact hole passing through the first insulating layer and the second insulating layer, and electrically connected to a semiconductor pattern included in each of the pixels, and a second connection electrode disposed on the fourth insulating layer, disposed in a contact hole passing through the third insulating layer and the fourth insulating layer, and connected to the first connection electrode, wherein each of the pixels may include a transistor including the semiconductor pattern disposed on the buffer layer and a gate area disposed on the first insulating layer and a light emitting element electrically connected to the semiconductor pattern through the first connection electrode and the second connection electrode.

The first connection electrode and the first conductive pattern may include the same material.

A non-conductive film (“NCF”) may be disposed between the driving chip and the pads.

The driving chip may include a base film and bumps protruding from the base film and connected to the pads.

The pads and the driving chip may be curved with a predetermined curvature with respect to the first direction.

In the first direction, a width of the first insulating pattern may be in a range of about 5 micrometers (μm) to about 8 μm, and a width of the second insulating pattern may be in a range of about 1 μm to about 4 μm.

A thickness of the second insulating pattern from an uppermost end of the first insulating pattern may be 30% or less of a maximum thickness of the first insulating pattern.

### BRIEF DESCRIPTION OF THE FIGURES

The above and other aspects and features of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of the electronic device according to an embodiment of the present disclosure.

FIG. 3 is a cross-sectional view of a display device according to an embodiment of the present disclosure.

FIG. 4 is a plan view of a display panel according to an embodiment of the present disclosure.

FIG. 5 is a cross-sectional view of any one pixel according to an embodiment of the present disclosure.

FIG. 6A is a cross-sectional view of a portion of the display device according to an embodiment of the present disclosure.

FIG. 6B is a plan view of an input sensing unit according to an embodiment of the present disclosure.

FIG. 7 is an enlarged perspective view of a partial area of the display device according to an embodiment of the present disclosure.

FIG. 8 is a cross-sectional view along line I-I′ of FIG. 7.

FIG. 9 is a cross-sectional view along line II-II′ of FIG. 7.

FIG. 10 is a cross-sectional view along line III-III′ of FIG. 7.

FIG. 11 is a cross-sectional view of a side pad according to an embodiment of the present disclosure.

FIG. 12 is a cross-sectional view of the side pad according to an embodiment of the present disclosure.

FIG. 13 is a cross-sectional view of the side pad according to an embodiment of the present disclosure.

FIGS. 14A to 14G are cross-sectional views illustrating a method of manufacturing the display panel according to an embodiment of the present disclosure.

### DETAILED DESCRIPTION

In the present specification, the expression that a first component (or area, layer, part, portion, etc.) is “on”, “connected with”, or “coupled to” a second component means that the first component is directly on, connected with, or coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the present specification have the same meaning as commonly understood by those skilled in the art to which the present disclosure belongs. Furthermore, terms such as terms defined in the dictionaries commonly used should be interpreted as having a meaning consistent with the meaning in the context of the related technology, and should not be interpreted in overly ideal or overly formal meanings unless explicitly defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5% or 2% of the stated value. Hereinafter, an embodiment of the present disclosure will be described with reference to accompanying drawings.

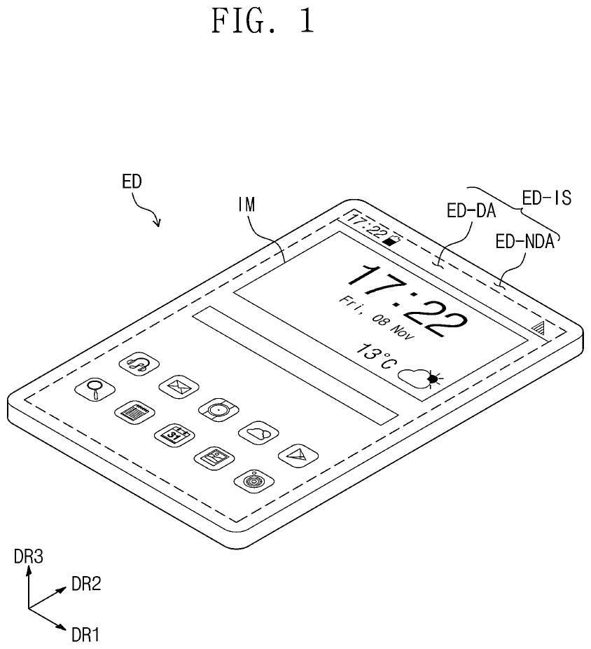

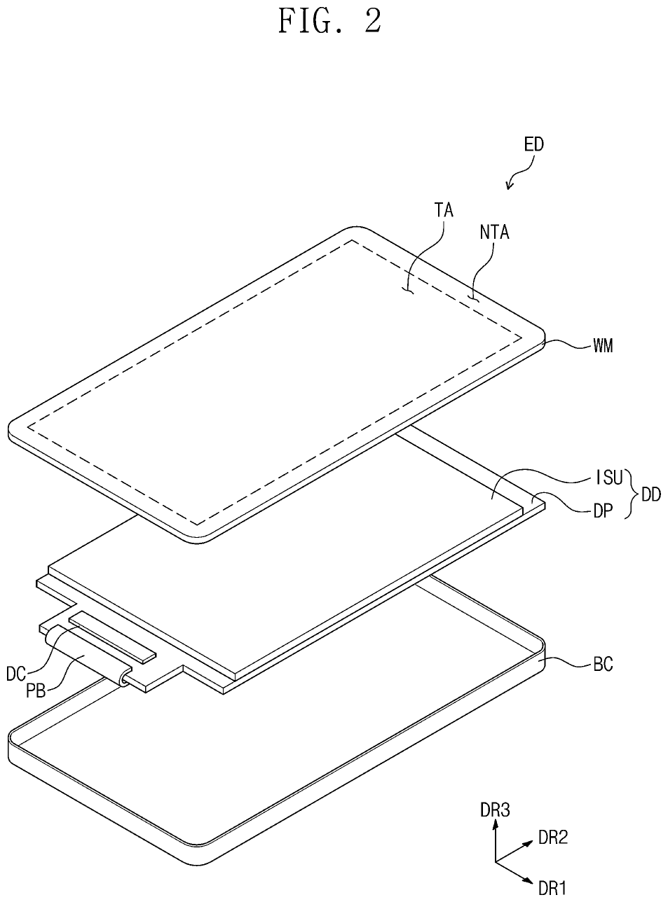

FIG. 1 is a perspective view of an electronic device according to an embodiment of the present disclosure. FIG. 2 is an exploded perspective view of the electronic device according to an embodiment of the present disclosure.

An electronic device ED may be a device that is activated according to an electric signal. In an embodiment, the electronic device ED is exemplarily illustrated as a smart phone. However, the present disclosure is not limited thereto, and the electronic device ED according to the present disclosure may be provided in an embodiment. For example, the electronic device ED may be applied to a personal computer (“PC”), a laptop computer, a television, a personal digital assistant, a vehicle navigation unit, a game console, a tablet, a camera, or the like.

The electronic device ED may display an image IM through a display surface ED-IS. In FIG. 1, icon images are illustrated as an example of the image IM. The display surface ED-IS may be parallel to a plane defined by a first direction DR1 and a second direction DR2.

Meanwhile, in FIG. 1 and the following drawings, the first direction DR1 to a third direction DR3 are illustrated, and directions indicated by the first to third directions DR1, DR2, and DR3 described in the specification are relative concepts and may be changed to different directions.

In the specification, for convenience of description, the third direction DR3 is defined as a direction in which an image is provided to a user. Further, the first direction DR1 and the second direction DR2 may be perpendicular to each other, and the third direction DR3 may be a normal direction to the plane defined by the first direction DR1 and the second direction DR2.

The display surface ED-IS may include a display area ED-DA that displays the image IM and a non-display area ED-NDA adjacent to the display area ED-DA. The non-display area ED-NDA may be an area that does not display an image. However, the present disclosure is not limited thereto, and the non-display area ED-NDA may be adjacent to one side of the display area ED-DA or may be omitted.

Referring to FIG. 2, the electronic device ED according to an embodiment may include a window WM, a display device DD, and a storage member BC.

The window WM may be disposed on the display device DD and transmit an image provided from the display device DD to the outside. The window WM may include a transmissive area TA and a non-transmissive area NTA.

The window WM may include a base layer and functional layers arranged on the base layer. The functional layers may include a protective layer, a fingerprint preventing layer, and the like. The base layer of the window WM may be made of glass, sapphire, or plastic. The base layer of the window WM may include an optically transparent insulating material. For example, the base layer of the window WM may include a glass or plastic film or may include a glass substrate and a plastic film bonded by an adhesive.

The transmissive area TA may overlap the display area ED-DA illustrated in FIG. 1 and have a shape corresponding to the display area ED-DA. The transmissive area TA may be an area that transmits, to the outside, the image IM (see FIG. 1) provided from the display device DD.

The non-transmissive area NTA may overlap the non-display area ED-NDA illustrated in FIG. 1 and have a shape corresponding to the non-display area ED-NDA. The non-transmissive area NTA may be an area having relatively low light transmittance compared to the transmissive area TA. The non-transmissive area NTA may be defined by a bezel pattern in a partial area of the base layer of the window WM, and an area in which the bezel pattern is not disposed may be defined as the transmissive area TA. However, the present disclosure is not limited thereto, and the non-transmissive area NTA may be omitted.

According to an embodiment, a reflection preventing layer may be disposed between the window WM and the display module DM. The reflection preventing layer may reduce reflectance of an external light beam input from the outside of the display device DD. The reflection preventing layer may include color filters. The color filters may have a predetermined arrangement. For example, the color filters may be arranged in consideration of light emitting colors of pixels included in a display panel DP, which will be described below. Further, the reflection preventing layer may further include a black matrix adjacent to the color filters.

The display device DD according to an embodiment may include a display panel DP and an input sensing unit ISU.

The display panel DP may be a liquid crystal display panel or a light emitting display panel. For example, the display panel DP may be a liquid crystal display panel including a liquid crystal element, an organic electroluminescent light emitting display panel including an organic electroluminescent light emitting element, or a quantum dot light emitting display panel including a quantum dot light emitting element. However, an embodiment is not limited thereto. Hereinafter, the display panel DP will be described as an organic light emitting display panel.

The input sensing unit ISU may be disposed on the display panel DP. The input sensing unit ISU may include any one of a capacitive sensor, an optical sensor, an ultrasonic sensor, and an electromagnetic induction sensor. The input sensing unit ISU may be formed on the display panel DP through a continuous process or may be separately manufactured and then attached to an upper portion of the display panel DP through an adhesive layer.

The display device DD may further include a driving chip DC and a circuit board PB arranged on the display panel DP.

In an embodiment, the circuit board PB may be a flexible circuit board. Hereinafter, the circuit board PB is described as the flexible circuit board and refers to the same reference numeral, but the present disclosure is not limited thereto. For example, the circuit board PB may be rigid. The flexible circuit board PB may electrically connect the display panel DP and a main circuit board.

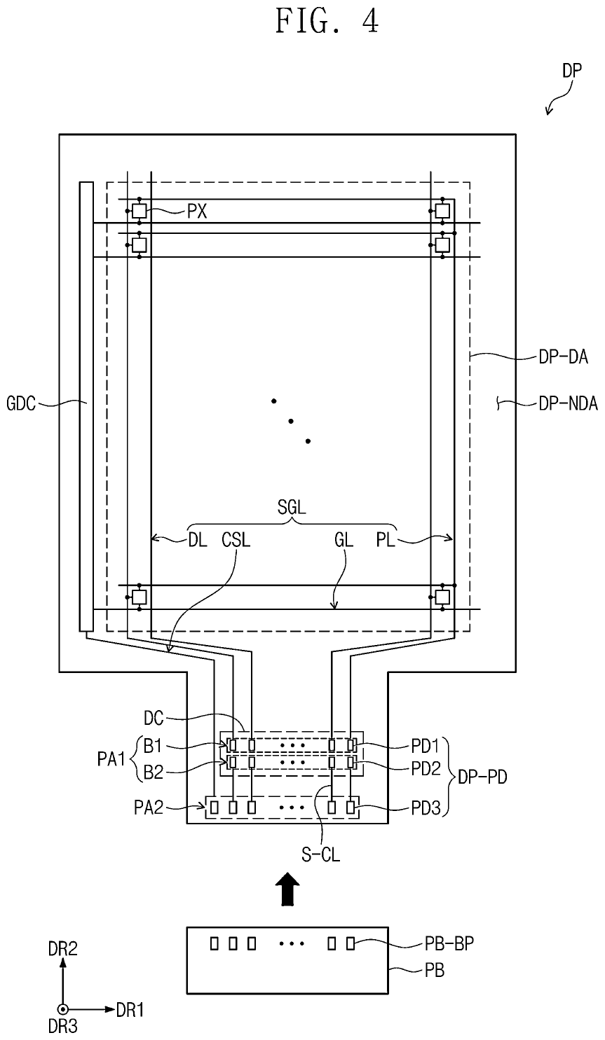

The driving chip DC may be mounted on the display panel DP. The driving chip DC may be an integrated circuit that is coupled to pads exposed to the display panel DP and is provided in the form of chip. The driving chip DC may be connected to at least some of signal lines connected to a pixel. The driving chip DC provides electrical signals to the pixels arranged in the display panel DP through the signal lines. The driving chip DC may be a data driving circuit D-IC that is connected to data lines DL (see FIG. 4) and provides data signals to the data lines DL.

The driving chip DC may be connected to the circuit board PB. The driving chip DC may include driving elements, for example, data driving circuits D-IC for driving the pixels of the display panel DP. In an embodiment, the driving chip DC directly mounted on the display panel DP and the flexible circuit board PB may be collectively referred to as electronic components. A bonding structure between the display panel DP and the flexible circuit board PB described below may be equally applied to other electronic components such as the driving chip DC other than the flexible circuit board PB.

According to an embodiment, a portion of the circuit board PB may be bent to face a rear surface of the display panel DP. However, the present disclosure is not limited thereto, and a portion of the display panel DP may be bent so that the driving chip DC faces a rear surface of the display device DD.

The storage member BC may accommodate the display device DD. The storage member BC may be coupled to the window WM to define an outer appearance of the electronic device ED. The storage member BC according to an embodiment may include a material having relatively high rigidity, and the storage member BC may absorb an impact applied from the outside. The storage member BC may be provided in a form in which a plurality of storage members are coupled.

The display device DD according to an embodiment may further include a main board accommodated in the storage member BC, electronic modules mounted on the main board, a camera module, a power supply module, and the like.

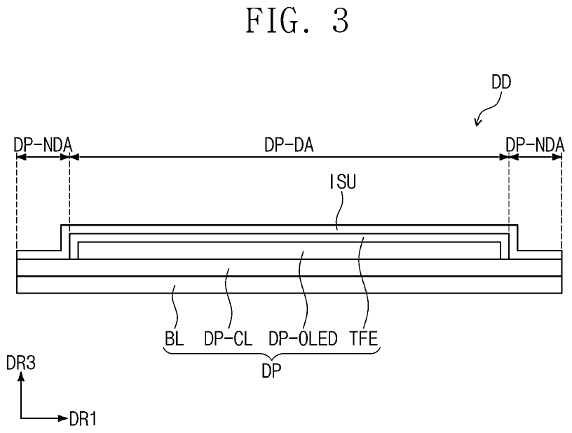

FIG. 3 is a cross-sectional view of a display device according to an embodiment.

The display panel DP may include a base layer BL, a circuit element layer DP-CL disposed on the base layer BL, a display element layer DP-OLED disposed on the circuit element layer DP-CL, and an encapsulation layer TFL disposed on the display element layer DP-OLED.

The display panel DP includes a display area DP-DA and a non-display area DP-NDA. The display area DP-DA of the display panel DP may correspond to the display area ED-DA of the electronic device ED described with reference to FIG. 1 and the transmissive area TA described with reference to FIG. 2. The non-display area DP-NDA of the display panel DP may correspond to the non-display area ED-NDA of the electronic device ED described with reference to FIG. 1 and the non-transmissive area NTA described with reference to FIG. 2.

The base layer BL may be disposed on a lowermost side of the display panel DP and provide a base surface on which components of the display panel DP are arranged. The base layer BL may include a synthetic resin layer. The synthetic resin layer may include a thermosetting resin. In particular, the synthetic resin layer may be a polyimide-based resin layer, and a material thereof is not particularly limited thereto. The synthetic resin layer may include at least one of an acrylic resin, a methacrylic resin, a polyisoprene, a vinyl resin, an epoxy resin, a urethane resin, a cellulose resin, a siloxane resin, a polyamide resin, and a perylene resin. In addition, the base layer BL may include a glass substrate, a metal substrate, an organic/inorganic composite material substrate, or the like.

The base layer BL may be provided in a form in which organic layers and inorganic layers are alternately laminated. For example, the base layer BL may be provided in a structure in which a first organic layer including polyimide, a first inorganic layer disposed on the first organic layer, a second organic layer including polyimide and disposed on the first inorganic layer, and a second inorganic layer disposed on the second organic layer are alternately laminated, and the present disclosure is not limited to an embodiment.

The circuit element layer DP-CL may include a plurality of insulating layers and a circuit element. The insulating layers may include at least one inorganic layer and at least one organic layer. The circuit element may include signal lines, a driving circuit, and the like. The insulating layers and the circuit element may be formed by forming an insulating layer, a semiconductor layer, and a conductive layer through processes such as coating and deposition, and then selectively patterning the insulating layer, the semiconductor layer, and the conductive layer through photolithography and etching processes. Therefore, a semiconductor pattern, a conductive pattern, a signal line and the like may be formed in the circuit element layer DP-CL.

Meanwhile, the patterns arranged on the same layer are formed through the same process. In the specification, the fact that the patterns are formed through the same process means that the patterns contain the same material and have the same laminated structure.

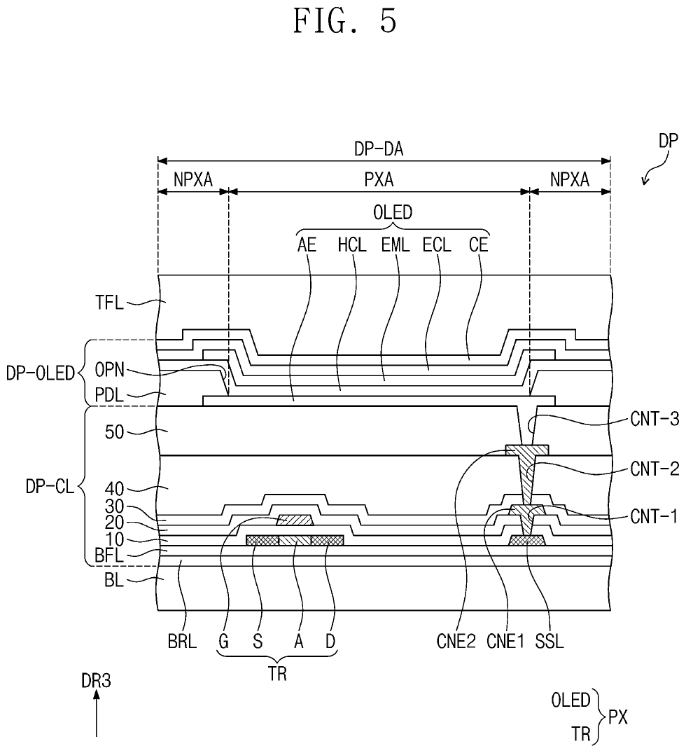

The display element layer DP-OLED may include a pixel defining film PDL (see FIG. 5) and an organic light emitting element OLED (see FIG. 5).

The encapsulation layer TFL may be disposed on the display element layer DP-OLED and cover the display element layer DP-OLED. The encapsulation layer TFL may prevent moisture/oxygen from permeating into the display element layer DP-OLED. The encapsulation layer TFL may include a laminated structure of an inorganic layer/organic layer/inorganic layer.

The input sensing unit ISU may be directly disposed on the display panel DP. In the specification, the wording “component A is directly disposed on component B” is defined as a state in which no other component is disposed between component A and component B.

FIG. 4 is a plan view of a display panel according to an embodiment. As used herein, the “plan view” is a view in a thickness direction (i.e., DR3) of the base layer BL.

Referring to FIG. 4, the display panel DP according to an embodiment may include pixels PX, a gate driving circuit GDC, signal lines SGL, and signal pads DP-PD.

The pixels PX may be arranged in the display area DP-DA. Each of the pixels PX may include the light emitting element OLED and a pixel driving circuit connected to the light emitting element OLED. In an embodiment, the light emitting element OLED may be an organic light emitting element.

The gate driving circuit GDC may be disposed in the non-display area DP-NDA of the display panel DP. The gate driving circuit GDC may sequentially output gate signals to gate lines GL. A transistor of the gate driving circuit GDC may be formed through the same process as the manufacturing process of a transistor of the pixel PX, for example, a low temperature polycrystalline silicon (“LTPS”) process, a low temperature polycrystalline oxide (“LTPO”) process, or a hybrid oxide and polycrystalline silicon (“HOP”) process.

However, the driving circuit included in the display panel DP is not limited to the gate driving circuit GDC, and the display panel DP may further include another driving circuit that provides a light emitting control signal to the pixels PX. For example, the display panel DP may include a scan driving circuit.

The signal lines SGL may be arranged in the display area DP-DA and the non-display area DP-NDA. The signal lines SGL may include the gate lines GL, the data lines DL, a power line PL, and a control signal line CSL. The gate lines GL may be connected to corresponding pixels PX among the pixels PX, and the data lines DL are connected to corresponding pixels PX among the pixels PX. The power line PL may be connected to the pixels PX. The control signal line CSL may provide control signals to the scan driving circuit.

The signal pads DP-PD may be arranged in the display area DP-DA. The signal pads DP-PD may include first pads PD1, second pads PD2, and third pads PD3.

The non-display area DP-NDA may include a first pad area PA1 and a second pad area PA2. The first pad area PA1 may be an area in which the first and second pads PD1 and PD2 are arranged and the driving chip DC (see FIG. 2) is disposed. The second pad area PA2 may be an area in which the third pads PD3 are arranged and the circuit board PB is disposed.

The first pad area PA1 and the second pad area PA2 may be spaced apart from each other in the second direction DR2.

The first pad area PA1 may include a first area B1 in which the first pads PD1 are arranged and a second area B2 in which the second pads PD2 are arranged. The first pads PD1 may be arranged in the first direction DR1 in the first area B1, and the second pads PD2 may be arranged in the first direction DR1 in the second area B2. Hereinafter, the area in which the first and second pads PD1 and PD2 are arranged may be defined as the first pad area PA1, and the area in which the third pads PD3 are arranged may be defined as the second pad area PA2.

The first pads PD1, the second pads PD2, and the third pads PD3 may be exposed to the outside in the non-display area DP-NDA among the insulating layers included in the display panel DP. A description related thereto will be made below.

In an embodiment, the first pads PD1 may be arranged in one row in the first area B1. The second pads PD2 may be arranged in one row in the second area B2. However, the number of arranged rows is not limited thereto. For example, the pads may be arranged in two or more rows in the corresponding areas.

Referring to FIG. 4, the second area B2 may be spaced apart from the first area B1 in the second direction DR2. The second pads PD2 arranged in the second area B2 may be connected to the third pads PD3 arranged in the second pad area PA2 through connection signal lines S-CL in a one-to-one correspondence.

The circuit board PB may include board bump electrodes PB-BP. The board bump electrodes PB-BP may be arranged in the first direction DR1. The board bump electrodes PB-BP of the circuit board PB may be in contact with and connected to the third pads PD3 of the second pad area PA2.

FIG. 5 is a cross-sectional view of the display panel according to an embodiment of the present disclosure. FIG. 5 illustrates a cross section corresponding to one light emitting area PXA and a portion of a non-light emitting area NPXA. The definitions of the light emitting area PXA and the non-light emitting area NPXA will be described below.

The display panel DP may include the base layer BL, the circuit element layer DP-CL disposed on the base layer BL, the display element layer DP-OLED disposed on the circuit element layer DP-CL, and the encapsulation layer TFL disposed on the display element layer DP-OLED.

For convenience of description, FIG. 5 illustrates only one transistor TR as an example of a driving circuit of the pixel PX, but an embodiment of the present disclosure is not limited thereto, and the pixel PX may include a plurality of transistors TR.

In an embodiment, the circuit element layer DP-CL may include a barrier layer BRL, a buffer layer BFL, first to fifth insulating layers 10 to 50, the transistor TR, a connection signal line SSL, a first connection electrode CNE1, and a second connection electrode CNE2. However, an embodiment of the present disclosure is not limited thereto, and the barrier layer BRL or the buffer layer BFL may be omitted, one or more layers of the first to fifth insulating layers 10, 20, 30, 40, and 50 may be omitted, or another insulating layer may be further included.

The barrier layer BRL is disposed on the base layer BL. The barrier layer BRL prevents inflow of foreign substances from the outside. The barrier layer BRL may include a silicon oxide layer and a silicon nitride layer. Each of the silicon oxide layer and the silicon nitride layer may be provided in plurality and the silicon oxide layers and the silicon nitride layers may be alternately laminated.

The buffer layer BFL is disposed on the barrier layer BRL. The buffer layer BFL may improve a coupling force between the base layer BL and the semiconductor pattern and/or the conductive pattern. The buffer layer BFL may include a silicon oxide layer and a silicon nitride layer. The silicon oxide layer and the silicon nitride layer may be alternately laminated.

The semiconductor pattern is disposed on the buffer layer BFL. The semiconductor pattern may include polysilicon. However, the present disclosure is not limited thereto, and the semiconductor pattern may include amorphous silicon or metal oxide.

FIG. 5 illustrates a portion of the semiconductor pattern, and an additional semiconductor pattern may be disposed in other areas of the display panel DP in a plan view. The semiconductor pattern may include a first area and a second area. The first area may be doped with an N-type dopant or a P-type dopant and may have greater conductivity than the conductivity of the second area. The first area substantially corresponds to an electrode or a signal line. The second area has a low doping concentration or may be a non-doped area, and substantially corresponds to an active (or a channel) of the transistor.

A drain “D,” an active “A,” and a source “S” may be arranged on the buffer layer BFL. The drain “D,” the active “A,” and the source “S” together with a gate “G” may define the transistor TR. When the display panel DP includes another transistor other than the transistor TR, the another transistor may include a material different from the material of the transistor TR and may be disposed on a different layer. The source “S,” the active “A,” the drain “D” of the transistor TR may be formed from the semiconductor pattern.

The first insulating layer 10 may be disposed on the buffer layer BFL. The first insulating layer 10 may cover the semiconductor pattern. The first insulating layer 10 may commonly overlap the plurality of pixels PX. The gate “G” is disposed on the first insulating layer 10. The gate “G” may be a portion of a metal pattern. The gate “G” may overlap the active “A” in a plan view. In a process of doping the semiconductor pattern, the gate “G” may function as a mask.

The gate “G” may include titanium (Ti), silver (Ag), an alloy containing silver, molybdenum (Mo), an alloy containing molybdenum, aluminum (Al), an alloy containing aluminum, aluminum nitride (“AIN”), tungsten (W), tungsten nitride (“WN”), copper (Cu), indium tin oxide (“ITO”), indium zinc oxide (“IZO”) or the like, but the present disclosure is not particularly limited thereto.

The second insulating layer 20 that covers the gate “G” may be disposed on the first insulating layer 10. The second insulating layer 20 may commonly overlap the pixels PX. The transistor TR according to an embodiment may further include an upper electrode (not shown) that is disposed on the second insulating layer 20 and overlaps the gate “G” in a plan view. The first connection electrode CNE1 may be connected to the connection signal line SSL through a contact hole CNT-1 passing through the first and second insulating layers 10 and 20. The connection signal line SSL may be electrically connected to the semiconductor pattern, even though it is not shown in FIG. 5.

The third insulating layer 30 that covers the first connection electrode CNE1 may be disposed on the second insulating layer 20. The first to third insulating layers 10 to 30 may be inorganic layers and/or organic layers and may have a single-layer or multi-layer structure.

The fourth insulating layer 40 may be disposed on the third insulating layer 30. The fourth insulating layer 40 may be an organic layer. The second connection electrode CNE2 may be disposed on the fourth insulating layer 40. The second connection electrode CNE2 may be connected to the first connection electrode CNE1 through a contact hole CNT-2 passing through the third and fourth insulating layers 30 and 40.

The fifth insulating layer 50 that covers the second connection electrode CNE2 may be disposed on the fourth insulating layer 40. The fifth insulating layer 50 may be an organic layer. A first electrode AE may be disposed on the fifth insulating layer 50. The first electrode AE may be connected to the second connection electrode CNE2 through a contact hole CNT-3 passing through the fifth insulating layer 50.

The display element layer DP-OLED may include the pixel defining film PDL and the light emitting element OLED. A pixel opening OPN may be defined in the pixel defining film PDL. The pixel opening OPN of the pixel defining film PDL may expose at least a portion of the first electrode AE. In an embodiment, the light emitting area PXA may be defined to correspond to a partial area of the first electrode AE, which is exposed by the pixel opening OPN.

A hole control layer HCL may be commonly disposed in the light emitting area PXA and the non-light emitting area NPXA. The hole control layer HCL may include a hole transport layer and may further include a hole injection layer.

A light emitting layer EML may be disposed on the hole control layer HCL. The light emitting layer EML may be disposed in an area corresponding to the pixel opening OPN. That is, the light emitting layer EML may be separately formed in each pixel. However, the present disclosure is not limited thereto, and the light emitting layer EML may be commonly formed in the plurality of pixels PX using an open mask.

An electron control layer ECL may be disposed on the light emitting layer EML. It is illustrated that the light emitting layer EML according to an embodiment is patterned for each pixel PX such that the light emitting layer EML is disposed on the one pixel opening OPN, but the present disclosure is not limited thereto, and the light emitting layer EML may be commonly disposed throughout the pixels PX, but an embodiment is not limited thereto.

According to an embodiment, the electron control layer ECL may include an electron transport layer and may further include an electron injection layer. The hole control layer HCL and the electron control layer ECL may be commonly formed in the plurality of pixels PX using an open mask.

A second electrode CE may be disposed on the electron control layer ECL. The second electrode CE may have an integral shape and may be commonly disposed in the pixels PX.

The encapsulation layer TFL may be disposed on the second electrode CE. The encapsulation layer TFL may include a plurality of thin films. For example, the encapsulation layer TFL may include inorganic layers and an organic layer covered by the inorganic layers.

The inorganic layers may protect the light emitting element OLED from moisture and/or oxygen. The inorganic layers may include at least one of an aluminum oxide, a titanium oxide, a silicon oxide, a silicon nitride, a silicon oxy nitride, a zirconium oxide, or a hafnium oxide. However, the materials of the inorganic layers are not limited to the above example.

The organic layer may protect the light emitting element OLED from foreign substances such as dust particles. For example, the organic layer may include an acrylic resin. However, the material of the organic layer is not limited to the above example.

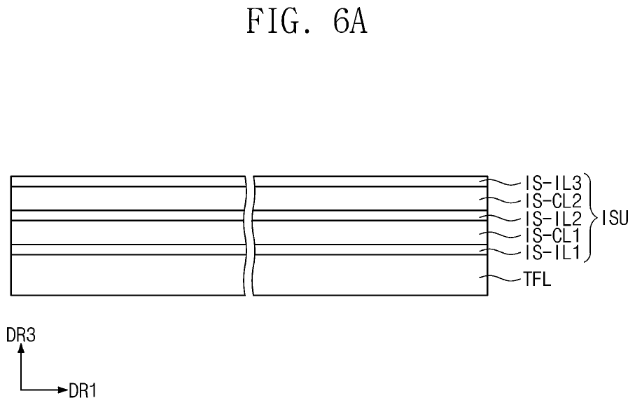

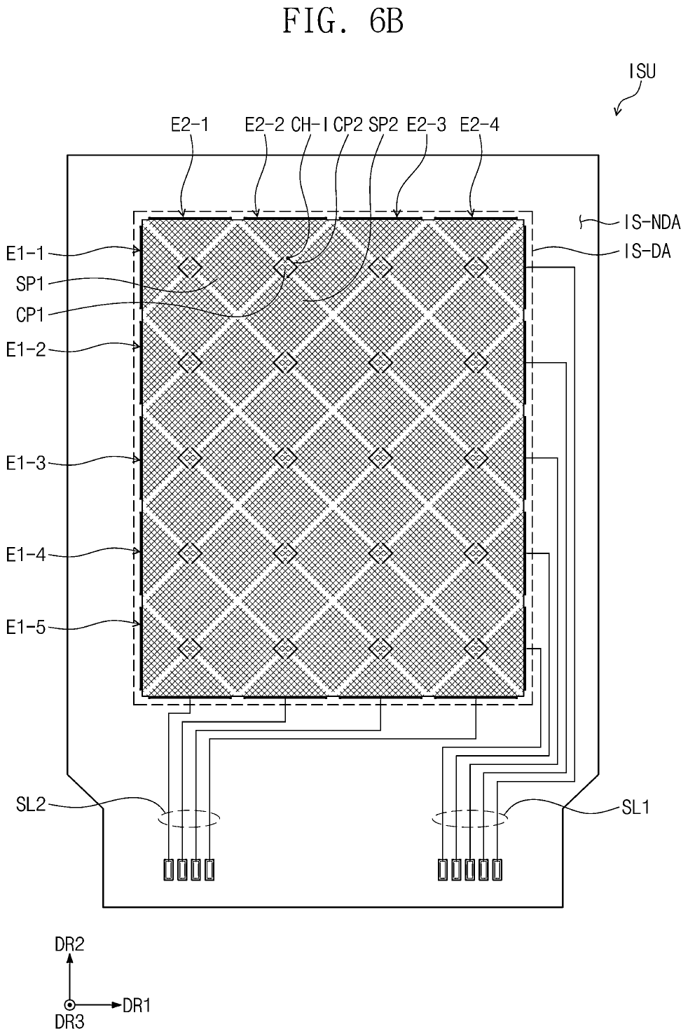

FIG. 6A is a cross-sectional view of a portion of the display device according to an embodiment of the present disclosure. FIG. 6B is a plan view of an input sensing unit according to an embodiment of the present disclosure.

Referring to FIG. 6A, the input sensing unit ISU may include a first sensing insulating layer IS-IL1, a first sensing conductive layer IS-CL1 disposed on the first sensing insulating layer IS-IL1, a second sensing insulating layer IS-IL2 disposed on the first sensing conductive layer IS-CL1, a second sensing conductive layer IS-CL2 disposed on the second sensing insulating layer IS-IL2, and a third sensing insulating layer IS-IL3 disposed on the second sensing conductive layer IS-CL2. The first sensing insulating layer IS-IL1 may be directly disposed on the encapsulation layer TFL.

However, the present disclosure is not limited thereto, and the first sensing insulating layer IS-IL1 and/or the third sensing insulating layer IS-IL3 may be omitted. When the first sensing insulating layer IS-IL1 is omitted, the first sensing conductive layer IS-CL1 may be directly disposed on the encapsulation layer TFL. The third sensing insulating layer IS-IL3 may be replaced with an adhesive layer or an insulating layer of a reflection preventing member of the input sensing unit ISU.

The first to third sensing insulating layers IS-IL1, IS-IL2, and IS-IL3 may each include an inorganic layer or an organic layer. The inorganic layer may include silicon oxide, silicon nitride, or silicon oxy nitride, and the organic layer may include at least one of an acrylic resin, a methacrylic resin, a polyisoprene, a vinyl resin, an epoxy resin, a urethane resin, a cellulose resin, a siloxane resin, a polyimide resin, a polyamide resin, and a perylene resin.

In an embodiment, at least one of the first to third sensing insulating layers IS-IL1, IS-IL2, and IS-IL3 may be the organic layer. For example, the third sensing insulating layer IS-IL3 may include an organic layer.

In FIG. 6A, for schematic expression of the laminated structure, each of the first sensing conductive layer IS-CL1 and the second sensing conductive layer IS-CL2 is illustrated as one layer overlapping the entire display panel DP. However, an embodiment is not limited thereto, and each of the first sensing conductive layer IS-CL1 and the second sensing conductive layer IS-CL2 may be patterned.

Referring to FIG. 6B, the input sensing unit ISU may include a sensing area IS-DA and a non-sensing area IS-NDA adjacent to the sensing area IS-DA. The sensing area IS-DA and the non-sensing area IS-NDA may correspond to the display area DP-DA (see FIG. 3) and the non-display area DP-NDA (see FIG. 3), respectively.

The input sensing unit ISU may include first electrodes E1-1 to E1-5, second electrodes E2-1 to E2-4, first trace lines SL1, and second trace lines SL2.

The first electrodes E1-1 to E1-5 and the second electrodes E2-1 to E2-4 may be arranged in the sensing area IS-DA. The first electrodes E1-1 to E1-5 and the second electrodes E2-1 to E2-4 may be insulated from and intersect each other.

The first trace lines SL1 and the second trace lines SL2 may be arranged in the non-sensing area IS-NDA. The first trace lines SL1 may be electrically connected to the first electrodes E1-1 to E1-5, respectively, and the second trace lines SL2 may be electrically connected to the second electrodes E2-1 to E2-4, respectively.

The first electrodes E1-1 to E1-5, the second electrodes E2-1 to E2-4, the first trace lines SL1, and the second trace lines SL2 may be a portion of the first sensing conductive layer IS-CL1 or the second sensing conductive layer IS-CL2.

The first electrodes E1-1 to E1-5 and the second electrodes E2-1 to E2-4 may include a plurality of conductive lines that intersect each other. The plurality of conductive lines may have a mesh shape that defines a plurality of openings. The conductive lines may overlap the pixel defining film PDL described in FIG. 5, and the openings defined by the conductive lines may overlap openings PDL-OP defined in the pixel defining film PDL in a plan view.

Each of the first electrodes E1-1 to E1-5 may include sensing portions SP1 and intermediate portions CP1 extending from the sensing portions SP1 and having a shape integral with the sensing portions SP1. That is, the sensing portions SP1 and the intermediate portions CP1 are integrated patterns patterned through the same process, but are separately described for convenience of description.

Each of the second electrodes E2-1 to E2-4 may include sensing patterns SP2 and bridge patterns CP2 (or connection patterns). The sensing patterns SP2 may be arranged in the second direction DR2. At least one bridge pattern CP2 may be disposed between the adjacent sensing patterns SP2. The bridge pattern CP2 may be arranged on the first sensing insulating layer IS-IL1, and the sensing patterns SP2 may be arranged on the second sensing insulating layer IS-IL2. Two adjacent sensing patterns SP2 may be connected to the bridge pattern CP2 through a contact hole CH-I passing through the second sensing insulating layer IS-IL2.

The first electrodes E1-1 to E1-5 and the sensing patterns SP2 may include a plurality of conductive lines that intersect each other. The plurality of conductive lines may define the plurality of openings, and each of the first electrodes E1-1 to E1-5 and the second electrodes E2-1 to E2-4 may have a mesh shape. Each of the plurality of openings may be defined to correspond to the openings PDL-OP of the pixel defining film PDL illustrated in FIG. 5.

The input sensing unit ISU according to an embodiment may detect an external input in a capacitance manner. For example, one of the first trace lines SL1 and the second trace lines SL2 transmits a transmission signal for detecting an external input from an external circuit, and the other one thereof transmits, as a reception signal, a change in capacitance between the first electrodes E1-1 to E1-5 and the second electrodes E2-1 to E2-4 to the external circuit.

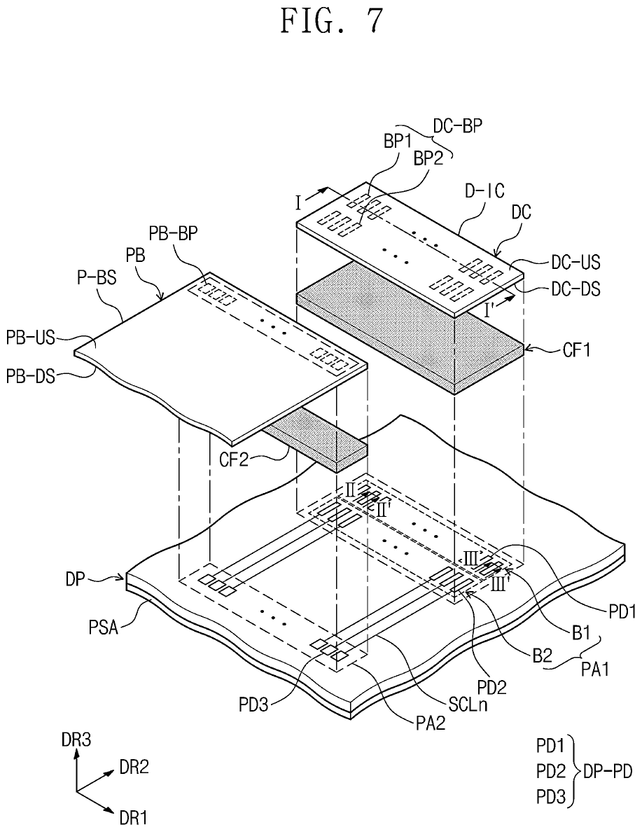

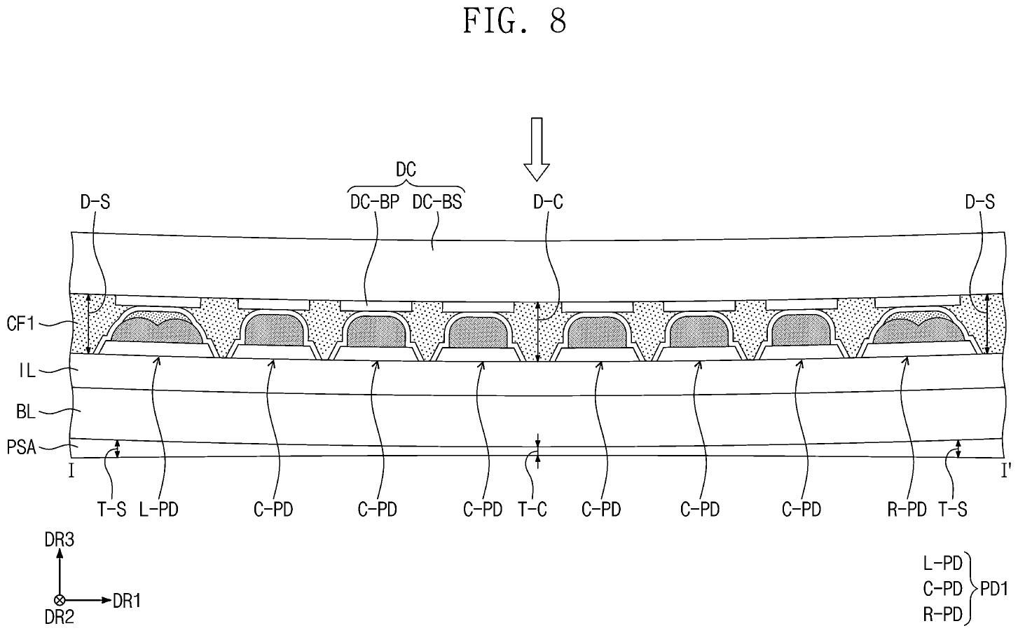

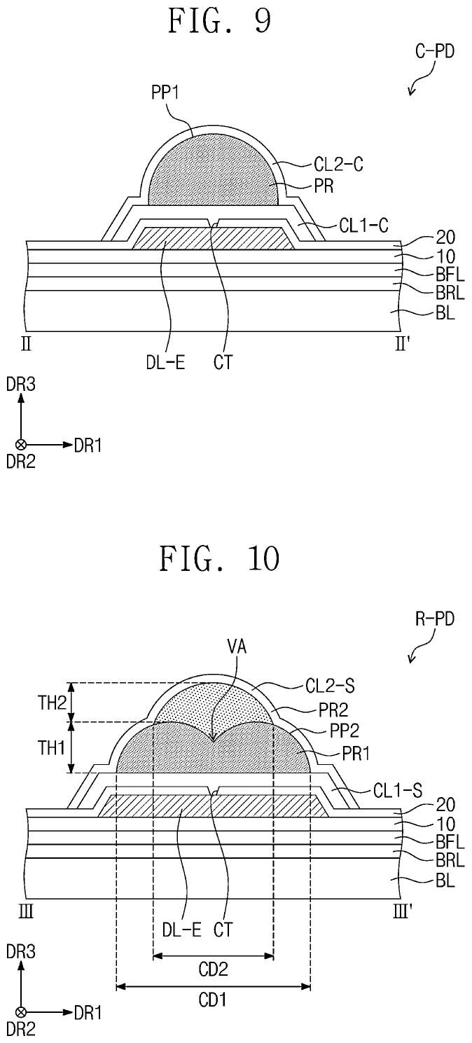

FIG. 7 is an enlarged perspective view of a partial area of the display device according to an embodiment of the present disclosure. FIG. 8 is a cross-sectional view along line I-I′ of FIG. 7. FIG. 9 is a cross-sectional view along line II-II′ of FIG. 7. FIG. 10 is a cross-sectional view along line III-III′ of FIG. 7.

FIG. 7 is an enlarged exploded perspective view of the pad areas PA1 and PA2 of the display device DD according to an embodiment of the present disclosure. Exemplarily, FIG. 7 illustrates the driving chip DC and the circuit board PB that are disassembled from the display panel DP. An arrangement relationship and a connection relationship between the first pad area PA1 and the second pad area PA2 have been described above with reference to FIG. 4, and thus duplicated description thereof will be omitted.

Referring to FIG. 7, the driving chip DC may include a base film DC-BS and a driving bump electrode DC-BP protruding from the base film DC-BS. The driving bump electrode DC-BP may include first bumps BP1 connected to the first pads PD1 in a one-to-one correspondence and second bumps BP2 connected to the second pads PD2 in a one-to-one correspondence.

A first film CF1 may be disposed between the driving chip DC and the first pad area PA1. According to the present disclosure, the first film CF1 may include a non-conductive film (NCF). Thus, the first film CF1 may include a synthetic resin having adhesive properties and may not include a conductive ball included in an anisotropic conductive film (“ACF”). The driving chip DC may include a rear surface DC-DS facing the display panel DP and an upper surface DC-US opposite to the rear surface DC-DS.

In a state in which the first film CF1 is disposed, the driving chip DC may electrically connect the driving bump electrode DC-BP and the first and second pads PD1 and PD2 arranged in the first pad area PA1 through a compression process.

According to an embodiment, when the compression process is performed, a lower film PSA may be disposed on the rear surface of the display panel DP. In the compression process, the lower film PSA may protect the display panel DP from an external impact applied to the display panel DP. The lower film PSA according to an embodiment may include a pressure sensitive adhesive.

The circuit board PB may include a base layer P-BS and the board bump electrodes PB-BP mounted on the circuit board PB. The circuit board PB may include an upper surface PB-US and a lower surface PB-DS, and the lower surface PB-DS of the circuit board PB may be a surface facing the third pads PD3. The circuit board PB may provide an image signal, a driving voltage, and other control signals to the driving chip DC.

The board bump electrodes PB-BP may be disposed on the lower surface PB-DS of the base layer P-BS. The board bump electrodes PB-BP may be connected to the third pads PD3 in a one-to-one correspondence. A second film CF2 may be disposed between the circuit board PB and the second pad area PA2. The board bump electrodes PB-BP may be connected to the third pads PD3 arranged in the second direction DR2 through a connection wiring line SCL.

According to an embodiment, the second film CF2 may include any one of the ACF and the NCF. When the ACF is disposed between the circuit board PB and the second pad area PA2, the board bump electrodes PB-BP and the third pads PD3 may be electrically connected in the compression process through the conductive ball included in the ACF.

When the NCF is disposed between the circuit board PB and the second pad area PA2, a shape related to the third pads PD3 may be the same as the shape of the first and second pads PD1 and PD2, which will be described below.

The driving chip DC may receive first signals through the second pads PD2 and the second bumps BP2. The driving chip DC may provide second signals generated based on the first signals to the first pads PD1 through the first bumps BP1. For example, the driving chip DC may include a data driving circuit D-IC and generate the second signals based on the first signals through the data driving circuit D-IC.

The first signal may be an image signal that is a digital signal applied from an external unit, and the second signal may be a data signal that is an analog signal. The driving chip DC may generate an analog voltage corresponding to a gradation value of the image signal. The data signal may be provided to the pixel PX through the data line DL (see FIG. 4).

FIG. 8 illustrates a state in which the driving bump electrodes DC-BP of the driving chip DC are in contact with the first pads PD1. The description of the first pads PD1, which will be made below, may also be applied to the second and third pads PD2 and PD3. In FIG. 8, for convenience of description, the insulating layers BFL, BRL, 10, and 20 described in FIG. 5 are illustrated as an insulating layer IL.

The first pads PD1 may be arranged in the first direction DR1. In the specification, pads arranged at opposite ends in the first direction DR1 among the first pads PD1 may be defined as side pads L-PD and R-PD. Pads arranged between the side pads L-PD and R-PD may be defined as central pads C-PD. The side pads L-PD and R-PD may have a laminated structure that is different from a structure of the center pads C-PD.

A thickness of the lower film PSA may be different in each area due to a pressure applied to the lower film PSA in a process of compressing the driving bump electrodes DC-BP and the first pads PD1. For example, a phenomenon may occur in which, in the process of compressing the driving bump electrodes DC-BP and the first pads PD1, the lower film PSA overlapping central portions of the first pads PD1 in a plan view is pushed to portions overlapping the side pads L-PD and R-PD due to a pressure. After the compression process, the display panel DP and the driving chip DC mounted thereon may be curved with a predetermined curvature with respect to the first direction DR1 as shown in FIG. 8.

After the compression process is performed, a thickness T-C of the lower film PSA overlapping the central portions of the first pads PD1 in a plan view may be smaller than a thickness T-S of the portions overlapping the side pads L-PD and R-PD in a plan view. In this case, when the side pads L-PD and R-PD and the central pads C-PD have the same thickness in the third direction DR3, that is, when the first pads PD1 have a constant size, a degree to which the first pads PD1 are pressed against the driving bump electrodes DC-BP may be different depending on positions of the first pads PD1. Accordingly, poor connection between the driving chip DC and the first pads PD1 may be caused.

According to the present disclosure, the side pads L-PD and R-PD having a relatively large compression amount have greater strength and/or greater density than those of the central pads C-PD having a relatively small compression amount due to a step of the lower film PSA, and thus the compression amounts of the side pads L-PD and R-PD may be effectively reduced.

Accordingly, even after the compression process, a distance D-S between the side pads L-PD and R-PD and the driving bump electrodes DC-BP and a distance D-C between the central pads C-PD and the driving bump electrodes DC-BP may be maintained the same or similar (including errors in a process). Accordingly, in the compression process, the compression amount is maintained constant for each position, and thus the display panel DP having improved bonding properties may be provided. Thus, the display device DD having improved reliability may be provided.

FIG. 9 illustrates one central pad C-PD, and FIG. 10 illustrate one side pad R-PD.

Referring to FIG. 9, the central pad C-PD may include a first conductive pattern CL1-C, an insulating pattern PR, and a second conductive pattern CL2-C.

The first conductive pattern CL1-C may be disposed on the second insulating layer 20. According to an embodiment, the first conductive pattern CL1-C may be connected to a data line DL-E through a contact hole CT defined in the second insulating layer 20. The data line DL-E may correspond to any one of the data lines DL in FIG. 4. The first conductive pattern CL1-C may include the same material as the material of the first connection electrode CNE1 described in FIG. 5. For example, the first conductive pattern CL1-C may include first to third conductive layers that are sequentially laminated. The first and third conductive layers may include titanium, and the second conductive layer may include aluminum.

The insulating pattern PR may be disposed on the first conductive pattern CL1-C. The insulating pattern PR may have a convex shape PP1 protruding in the third direction DR3 before compressed together with the driving bump electrode DC-BP (see FIG. 8). The insulating pattern PR may include polymer. The insulating pattern PR according to an embodiment may include any one of a negative photoresist (PR) and a positive photoresist (PR).

The second conductive pattern CL2-C may cover the insulating pattern PR and a lateral side of an upper surface of the first conductive pattern CL1-C, which is exposed from the insulating pattern PR. The second conductive pattern CL2-C may include the same material as the material of the second connection electrode CNE2 described in FIG. 5. For example, the second conductive pattern CL2-C may include first to third conductive layers that are sequentially laminated. The first and third conductive layers may include titanium, and the second conductive layer may include aluminum. When the compression process is performed, the second conductive pattern CL2-C may be in contact with the driving bump electrode DC-BP.

Referring to FIG. 10, the side pad R-PD may include a first conductive pattern CL1-S, a first insulating pattern PR1, a second insulating pattern PR2, and a second conductive pattern CL2-S.

The first conductive pattern CL1-S may be disposed on the second insulating layer 20. According to an embodiment, the first conductive pattern CL1-S may be connected to the data line DL-E through the contact hole CT defined in the second insulating layer 20. The data line DL-E may correspond to any one of the data lines DL in FIG. 4. The first conductive pattern CL1-S may include the same material as the material of the first connection electrode CNE1 described in FIG. 5. For example, the first conductive pattern CL1-C may include first to third conductive layers that are sequentially laminated. The first and third conductive layers may include titanium, and the second conductive layer may include aluminum.

The first insulating pattern PR1 may be disposed on the first conductive pattern CL1-C. The first insulating pattern PR1 may include protruding patterns PP2 that protrude in the third direction DR3 before compressed together with the driving bump electrode DC-BP (see FIG. 8). Lower portions of the protruding patterns PP2 may have an integrated shape in which the lower portions are connected to each other. A valley VA recessed in a direction toward the base layer BL may be defined between the protruding patterns PP2. The valley VA may be formed by patterning the first insulating pattern PR1 with a half-tone mask. The first insulating pattern PR1 may include polymer. The first insulating pattern PR1 according to an embodiment may include any one of a negative photoresist (PR) and a positive photoresist (PR).

The second insulating pattern PR2 may be disposed on the first insulating pattern PR1. The second insulating pattern PR2 may overlap the valley VA defined in the first insulating pattern PR1 in a plan view. The second insulating pattern PR2 may include polymer. When the first insulating pattern PR1 includes the positive photoresist (PR), the second insulating pattern PR2 according to an embodiment may include any one of the negative photoresist (PR) and the positive photoresist (PR). The present disclosure is not limited thereto, when the first insulating pattern PR1 includes the negative photoresist (PR), the second insulating pattern PR2 may include the negative photoresist (PR).

The second conductive pattern CL2-S may cover the second insulating pattern PR2, a portion of the first insulating pattern PR1 exposed from the second insulating pattern PR2, and a lateral side of an upper surface of the first conductive pattern CL1-S, which is exposed from the first insulating pattern PR1. The second conductive pattern CL2-S may include the same material as the material of the second connection electrode CNE2 described in FIG. 5. For example, the second conductive pattern CL2-S may include first to third conductive layers that are sequentially laminated. The first and third conductive layers may include titanium, and the second conductive layer may include aluminum. When the compression process is performed, the second conductive pattern CL2-S may be in contact with the driving bump electrode DC-BP.

A first thickness TH1 of the first insulating pattern PR1 in the third direction DR 3 may be greater than a second thickness TH2 of the second insulating pattern PR2 in the third direction DR 3. In an embodiment, the first thickness TH1 may be a maximum thickness of the first insulating pattern PR1 and the second thickness TH2 of the second insulating pattern PR2 may be measured from an uppermost end of the first insulating pattern PR1 and may be 30% or less of the first thickness TH1 of the first insulating pattern PR1. The second thickness TH2 may be 5% or more of the first thickness TH1.

A first width CD1 of the first insulating pattern PR1 in the first direction DR1 may be in a range of about 5 μm to about 8 μm. A second width CD2 of the second insulating pattern PR2 in the first direction DR1 may be in a range of about 1 μm to about 4 μm. The first width CD1 may be greater than the second width CD2.

According to an embodiment, the side pads R-PD and L-PD arranged at opposite ends in the first direction DR1 among the first pads PD1 include the insulating patterns PR1 and PR2 that are sequentially laminated, and thus may have greater strength and/or greater density than those of the central pads PD-C arranged between the side pads R-PD and L-PD. Accordingly, the compression amounts of the side pads R-PD and L-PD caused by the step of the lower film PSA in the compression process may be effectively reduced.

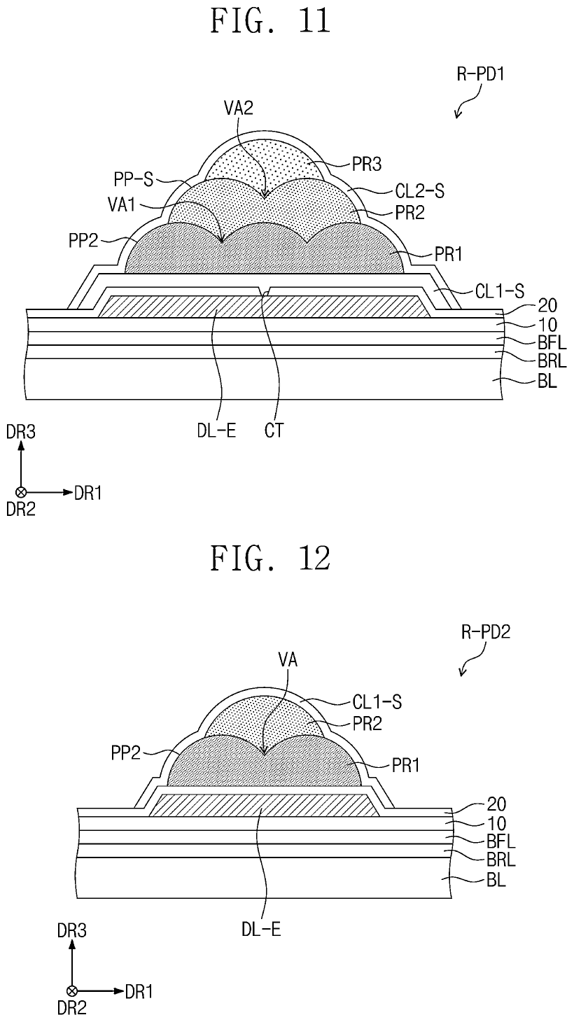

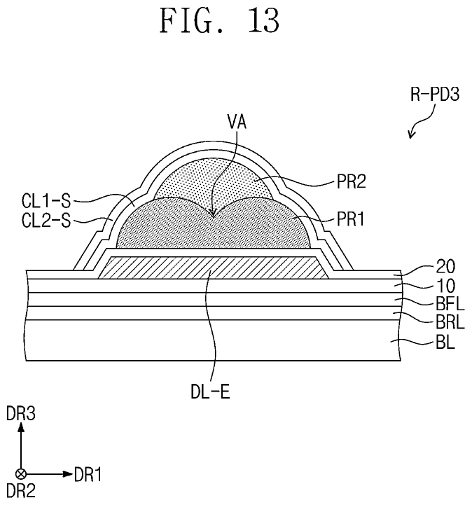

FIG. 11 is a cross-sectional view of a side pad according to an embodiment of the present disclosure. FIG. 12 is a cross-sectional view of the side pad according to an embodiment of the present disclosure. FIG. 13 is a cross-sectional view of the side pad according to an embodiment of the present disclosure. The same/similar reference numerals are used for the same/similar components described in FIGS. 7 to 10, and a duplicated description thereof will be omitted.

Referring to FIG. 11, the side pad R-PD may include the first conductive pattern CL1-S, the first insulating pattern PR1, the second insulating pattern PR2, a third insulating pattern PR3, and the second conductive pattern CL2-S.

The first conductive pattern CL1-S may be disposed on the second insulating layer 20. According to an embodiment, the first conductive pattern CL1-S may be connected to the data line DL-E through the contact hole CT defined in the second insulating layer 20.

The first insulating pattern PR1 may be disposed on the first conductive pattern CL1-C. The first insulating pattern PR1 may include the protruding patterns PP2 that protrude in the third direction DR3 before compressed together with the driving bump electrode DC-BP (see FIG. 8). The lower portions of the protruding patterns PP2 may have an integrated shape in which the lower portions are connected to each other. At least one valley VA1 recessed in the direction toward the base layer BL may be defined between the protruding patterns PP2. According to an embodiment, the first insulating pattern PR1 may include three protruding patterns PP2, and two valleys VA1 may be defined between the three protruding patterns PP2.

The valleys VA1 may be formed by patterning the first insulating pattern PR1 with a half-tone mask. The first insulating pattern PR1 may include polymer.

The second insulating pattern PR2 may be disposed on the first insulating pattern PR1. The second insulating pattern PR2 may include sub-protruding patterns PP-S overlapping the valleys VA1 defined in the first insulating pattern PR1 in a plan view. Lower portions of the sub-protruding patterns PP-S may have an integrated shape in which the lower portions are connected to each other. At least one sub-valley VA2 recessed in the direction toward the base layer BL may be defined between the sub-protruding patterns PP-S. According to an embodiment, the second insulating pattern PR2 may include two sub-protruding patterns PP-S, and the one sub-valley VA2 may be defined between the two sub-protruding patterns PP-S.

The third insulating pattern PR3 may be disposed on the second insulating pattern PR2. The third insulating pattern PR3 may overlap the sub-valley VA2 defined in the second insulating pattern PR2 in a plan view. The third insulating pattern PR3 may include polymer.

The second conductive pattern CL2-S may cover the third insulating pattern PR3, a portion of the second insulating pattern PR2 exposed from the third insulating pattern PR3, a portion of the first insulating pattern PR1 exposed from the second insulating pattern PR2, and the lateral side of the upper surface of the first conductive pattern CL1-S, which is exposed from the first insulating pattern PR1. The second conductive pattern CL2-S may include the same material as the material of the second connection electrode CNE2 described in FIG. 5.

Referring to FIG. 12, a side pad R-PD2 may include the first conductive pattern CL1-S, the first insulating pattern PR1, and the second insulating pattern PR2.

The first insulating pattern PR1 may be disposed on the second insulating layer 20. The first insulating pattern PR1 may include the protruding patterns PP2 that protrude in the third direction DR3 before compressed together with the driving bump electrode DC-BP (see FIG. 8). The lower portions of the protruding patterns PP2 may have an integrated shape in which the lower portions are connected to each other. The valley VA recessed in the direction toward the base layer BL may be defined between the protruding patterns PP2. The valley VA may be formed by patterning the first insulating pattern PR1 with a half-tone mask. The first insulating pattern PR1 may include polymer.

The second insulating pattern PR2 may be disposed on the first insulating pattern PR1. The second insulating pattern PR2 may overlap the valley VA defined in the first insulating pattern PR1 in a plan view. The second insulating pattern PR2 may include polymer.

The first conductive pattern CL1-S may cover the second insulating pattern PR2, a portion of the first insulating pattern PR1 exposed from the second insulating pattern PR2, and a portion of the second insulating layer 20. The first conductive pattern CL1-S may include the same material as the material of the first connection electrode CNE1 described in FIG. 5. According to an embodiment, the second conductive pattern CL2-S described in FIG. 10 may be omitted.

FIG. 13 will be mainly described focusing on the difference from FIG. 12. Referring to FIG. 13, a side pad R-PD3 may include the first insulating pattern PR1, the second insulating pattern PR2, the first conductive pattern CL1-S, and the second conductive pattern CL2-S.

The first insulating pattern PR1 may be disposed on the second insulating layer 20. The second insulating pattern PR2 may be disposed on the first insulating pattern PR1. The first conductive pattern CL1-S may cover the second insulating pattern PR2, a portion of the first insulating pattern PR1 exposed from the second insulating pattern PR2, and the portion of the second insulating layer 20. According to an embodiment, the second conductive pattern CL2-S may cover the first conductive pattern CL1-S.

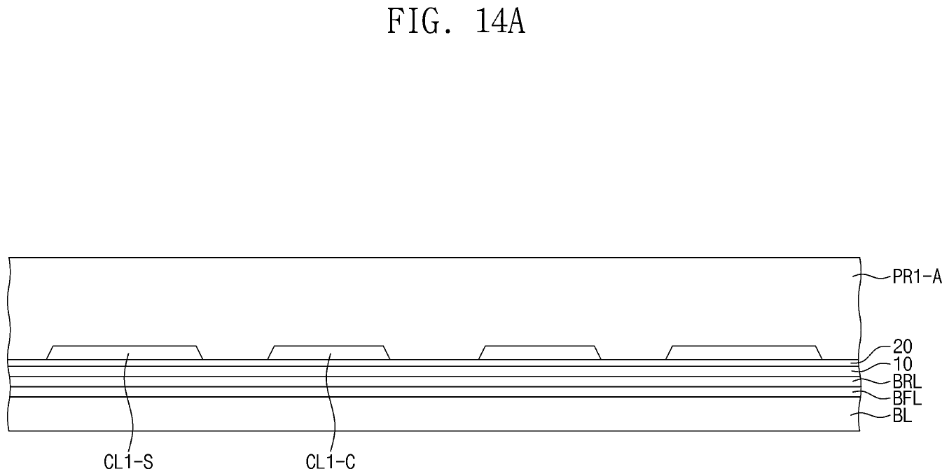

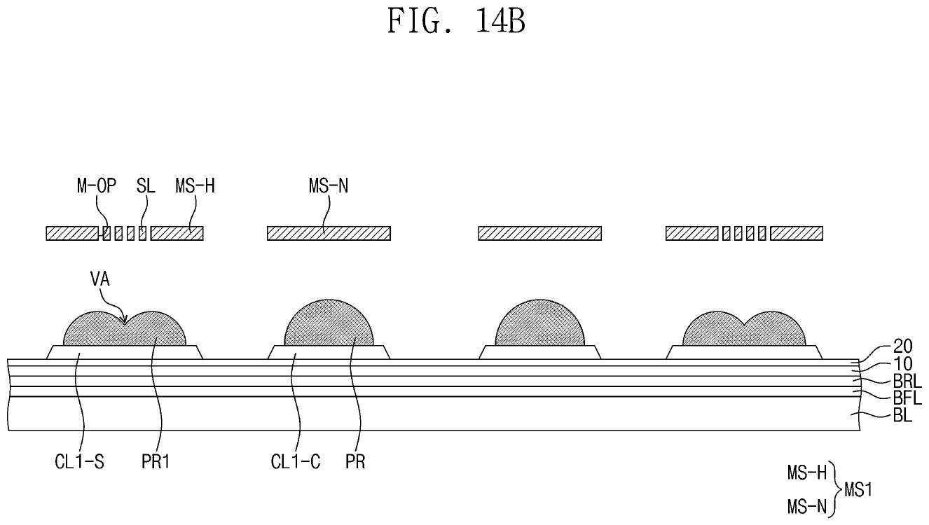

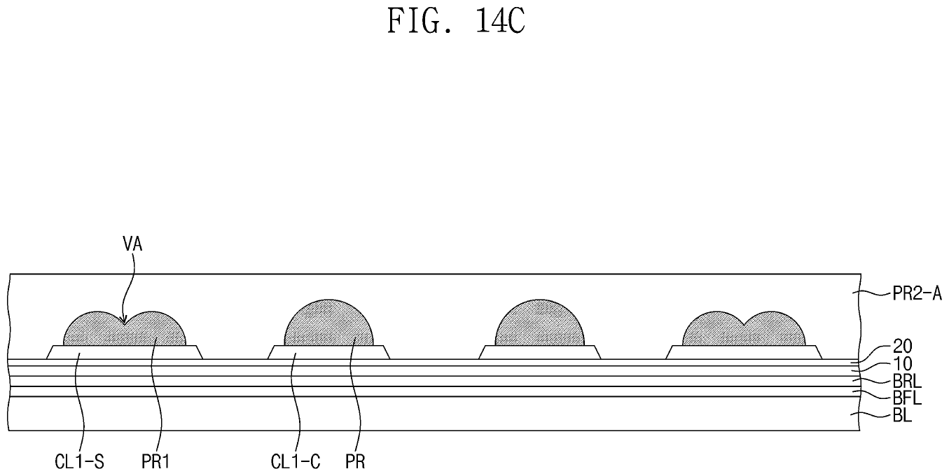

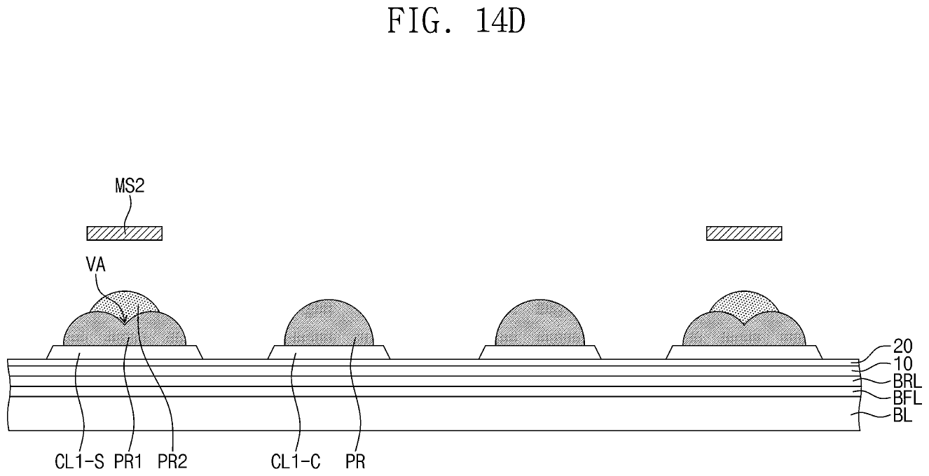

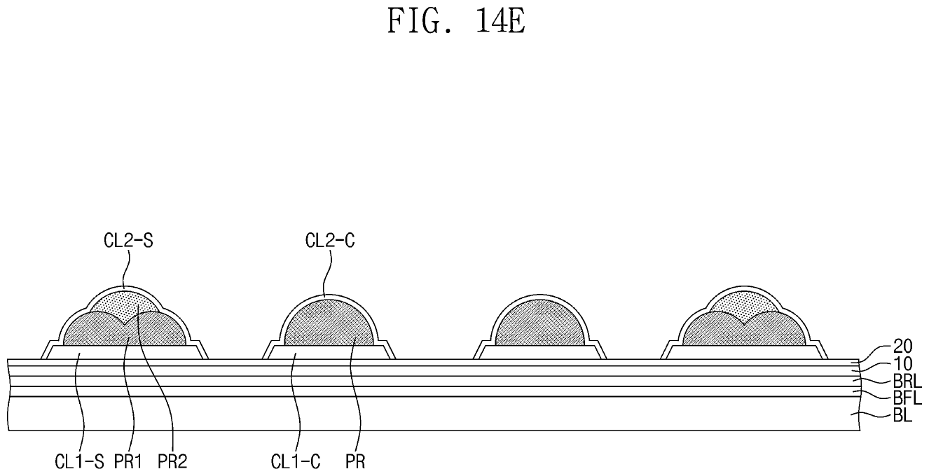

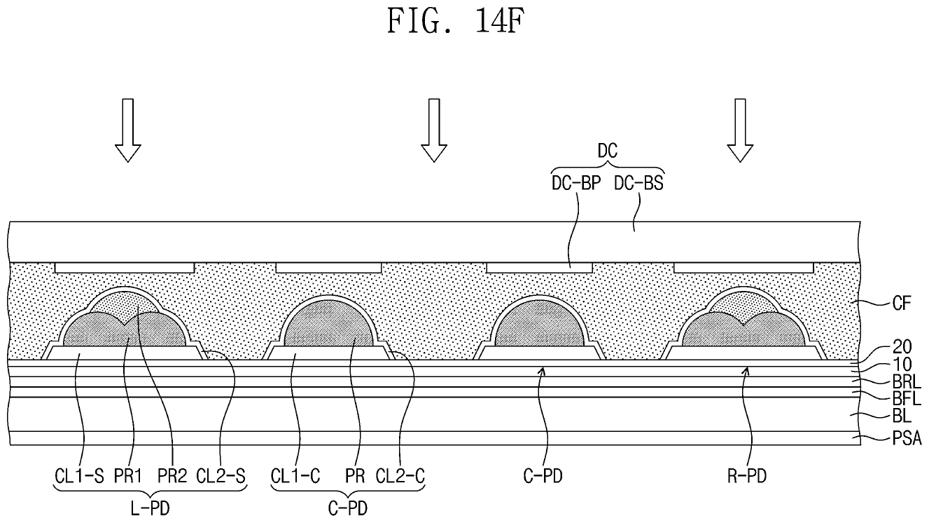

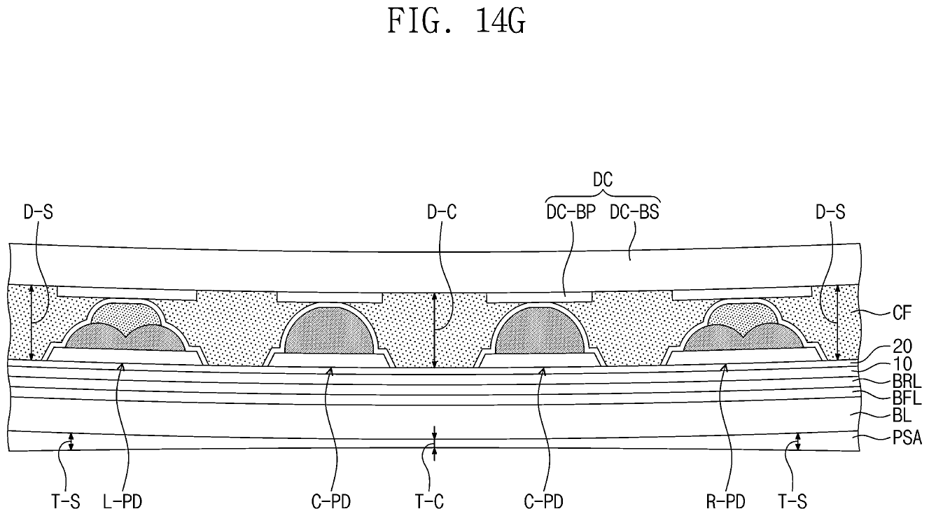

FIGS. 14A to 14G are cross-sectional views illustrating a method of manufacturing the display panel according to an embodiment of the present disclosure.

Referring to FIG. 14A, the method may include an operation of forming a first polymer PR1-A on a preliminary substrate. The preliminary substrate may be provided in a state in which the insulating layers BFL, BRL, 10, and 20 and the first conductive patterns CL1-C and CL1-S that are arranged on the base layer BL described in FIG. 5 are formed. The first conductive patterns CL1-C and CL1-S may be formed on the second insulating layer 20 and spaced apart from each other. The first polymer PR1-A may be formed on the second insulating layer 20 and cover the first conductive patterns CL1-C and CL1-S. The first polymer PR1-A may include any one of a negative photoresist (PR) and a positive photoresist (PR).

Thereafter, referring to FIG. 14B, the method may include an operation of patterning the first polymer PR1-A. The operation of patterning the first polymer PR1-A may be performed in a photoresist process using a first mask MS1.

A half-tone mask MS-H may be disposed on first side conductive patterns CL1-S arranged at opposite ends among the first conductive patterns CL1-C and CL1-S, and a normal mask MS-N may be disposed on first central conductive patterns CL1-C arranged between the first side conductive patterns CL1-S. The half-tone mask MS-H may include a plurality of slits SL that are spaced apart from each other. A mask opening M-OP may be defined between the slits LS.

When the photoresist process is performed on the first polymer PR1-A through the first mask MS1, the first insulating pattern PR1 may be formed on the first side conductive patterns CL1-S, and the insulating patterns PR may be formed on the first central conductive patterns CL1-C. The insulating pattern PR may have a convex shape that protrudes in a thickness direction (i.e., third direction DR3). Protruding patterns that protrude in the third direction DR3 may be formed in the first insulating pattern PR1. Lower portions of the protruding patterns may have an integrated shape in which the lower portions are connected to each other. The valley VA recessed in the direction toward the base layer BL may be defined between the protruding patterns.

Thereafter, referring to FIG. 14C, the method may include an operation of forming a second polymer PR2-A on the second insulating layer 20. The second polymer PR2-A may cover the first insulating patterns PR1 and the insulating patterns PR. When the first polymer PR1-A includes a positive photoresist (PR), the second polymer PR2-A may include a positive photoresist (PR).

Thereafter, referring to FIG. 14D, the method may include an operation of patterning the second polymer PR2-A. The operation of patterning the second polymer PR2-A may be performed in the photoresist process using a second mask MS2.

The second mask MS2 may be disposed on only the first insulating pattern PR1. Accordingly, the second insulating pattern PR2 overlapping the valley VA in a plan view may be formed on the first insulating pattern PR1. The second polymer PR2-A disposed on the insulating pattern PR may be removed.

Thereafter, referring to FIG. 14E, the method may include an operation of forming the second conductive patterns CL2-C and CL2-S. The second conductive patterns CL2-C and CL2-S may be formed in the same process as the manufacturing process of the second connection electrode CNE2 described in FIG. 5. Each of the second central conductive patterns CL2-C may cover the insulating pattern PR. A portion of the second central conductive pattern CL2-C may be in contact with the first central conductive pattern CL1-C. Each of the second side conductive patterns CL2-S may cover the second insulating pattern PR2 and a portion of the first insulating pattern PR1 exposed from the second insulating pattern PR2. A portion of the second side conductive pattern CL2-S may be in contact with the first side conductive pattern CL1-S.

Each of the side pads L-PD and R-PD may include the first conductive pattern CL1-S, the first insulating pattern PR1, the second insulating pattern PR2, and the second conductive pattern CL2-S, and each of the central pads C-PD may include the first conductive pattern CL1-C, the insulating pattern PR, and the second conductive pattern CL2-C.

Thereafter, referring to FIG. 14F, the method may include an operation of arranging the driving bump electrodes DC-BP of the driving chip DC and the pads L-PD, R-PD, and C-PD. The driving chip DC may include the driving bump electrodes DC-BP that protrude from a lower surface of the driving chip DC. The driving bump electrodes DC-BP may correspond to the pads L-PD, R-PD, and C-PD in a one-to-one correspondence. That is, the driving bump electrodes DC-BP may overlap the pads L-PD, R-PD, and C-PD in a one-to-one correspondence in a plan view. A non-conductive film CF may be disposed between the driving bump electrodes DC-BP and the pads L-PD, R-PD, and C-PD.

Thereafter, referring to FIG. 14G, the method may include an operation of compressing the driving bump electrodes DC-BP and the pads L-PD, R-PD, and C-PD. Before the compression process, the lower film PSA may be attached to a lower surface of the base layer BL. The lower film PSA may protect components arranged on the base layer BL from an external impact. The lower film PSA according to an embodiment may include a pressure sensitive adhesive.

In the compression process, in a process of compressing the driving bump electrodes DC-BP and the pads L-PD, R-PD, and C-PD, a thickness of the lower film PSA may be different in each area due to a pressure applied to the lower film PSA. For example, a phenomenon may occur in which, in a process of compressing the driving bump electrodes DC-BP and the pads L-PD, R-PD, and C-PD, the lower film PSA overlapping central portions of the central pads C-PD in a plan view is pushed to portions overlapping the side pads L-PD and R-PD due to a pressure. After the compression process, a section from the base layer BL to the driving chip DC may be curved with a predetermined curvature with respect to the first direction DR1.

After the compression process is performed, a thickness T-C of the lower film PSA overlapping the central portions of the central pads C-PD may be smaller than a thickness T-S of the portions overlapping the side pads L-PD and R-PD.

In the method of manufacturing a display device according to the present disclosure, the side pads L-PD and R-PD may include the laminated insulating patterns PR1 and PR2 and thus have a greater strength and/or a greater density than a strength and/or density of the central pads C-PD. Accordingly, the compression amounts of the side pads L-PD and R-PD may be reduced, and the reliability of the process of compressing the driving bump electrodes DC-BP and the pads L-PD, R-PD, and C-PD may effectively increase.

According to an embodiment of the present disclosure, by maintaining a constant compression amount for each position in a compression process, a display panel having improved bonding properties may be provided. Thus, a display device having improved reliability may be provided.

Although the description has been made above with reference to an embodiment of the present disclosure, it may be understood that those skilled in the art or those having ordinary knowledge in the art may variously modify and change the present disclosure without departing from the spirit and technical scope of the present disclosure described in the appended claims.

Thus, the technical scope of the present disclosure is not limited to the detailed description of the specification, but should be defined by the appended claims.

What is claimed is:

1. A display device comprising:
a base layer including a display area and a non-display area adjacent to the display area;
insulating layers disposed on the base layer;
pixels disposed in the display area;
pads connected to the pixels, arranged in a first direction, and disposed in the non-display area; and
a driving chip connected to the pads,
wherein each of side pads arranged at opposite ends in the first direction among the pads includes:
a first conductive pattern;
a first insulating pattern including protruding patterns, which protrude in a direction toward the driving chip; and
a second insulating pattern disposed on the first insulating pattern.

2. The display device of claim 1, wherein the protruding patterns have an integral shape in which lower portions of the protruding patterns are connected,
a valley recessed in a direction toward the base layer is defined between the protruding patterns, and
the second insulating pattern overlaps the valley in a plan view.

3. The display device of claim 1, wherein two valleys recessed in a direction toward the base layer are defined between the protruding patterns,
the second insulating pattern further includes sub-protruding patterns, which protrude in the direction toward the driving chip and overlap the two valleys in a plan view, respectively,
one sub-valley recessed in the direction toward the base layer is defined between the sub-protruding patterns, and
each of the side pads further includes a third insulating pattern disposed on the second insulating pattern and overlapping the sub-valley in the plan view.

4. The display device of claim 1, wherein each of the side pads further includes a second conductive pattern covering the second insulating pattern and a portion of the first insulating pattern exposed from the second insulating pattern.

5. The display device of claim 4, wherein the second conductive pattern includes first to third conductive layers that are sequentially laminated, and
the first conductive layer and the third conductive layer include titanium, and the second conductive layer includes aluminum.

6. The display device of claim 1, wherein the first conductive pattern covers the second insulating pattern and a portion of the first insulating pattern exposed from the second insulating pattern.

7. The display device of claim 1, wherein the first conductive pattern covers the second insulating pattern and a portion of the first insulating pattern exposed from the second insulating pattern, and
each of the side pads further includes a second conducive pattern covering the first conductive pattern.

8. The display device of claim 1, wherein the first insulating pattern includes a positive photoresist (PR), and the second insulating pattern includes one of the positive photoresist (PR) and a negative photoresist (PR).

9. The display device of claim 1, wherein the first insulating pattern includes a negative photoresist (PR), and the second insulating pattern includes the negative photoresist (PR).

10. The display device of claim 1, wherein the first insulating pattern and the second insulating pattern include polymer.

11. The display device of claim 1, wherein each of central pads arranged between the side pads among the pads includes:
a third conductive pattern;
an insulating pattern having a convex shape, which protrudes in the direction toward the driving chip; and
a fourth conductive pattern covering the insulating pattern.

12. The display device of claim 1, wherein the insulating layers include a barrier layer disposed on the base layer, a buffer layer disposed on the barrier layer, and first to fifth insulating layers arranged on the buffer layer, and
each of the third to fifth insulating layers exposes the second insulating layer in the non-display area, and the first conductive pattern is disposed on the second insulating layer.

13. The display device of claim 12, further comprising:
data lines configured to connect the pixels and the pads, disposed on the first insulating layer, and covered by the second insulating layer,
wherein the first conductive patterns are arranged in contact holes passing through the second insulating layer and connected to the data lines.

14. The display device of claim 12, further comprising:
a first connection electrode disposed on the second insulating layer, disposed in a contact hole passing through the first insulating layer and the second insulating layer, and electrically connected to a semiconductor pattern included in each of the pixels; and
a second connection electrode disposed on the fourth insulating layer, disposed in a contact hole passing through the third insulating layer and the fourth insulating layer, and connected to the first connection electrode,
wherein each of the pixels includes a transistor including the semiconductor pattern disposed on the buffer layer and a gate disposed on the first insulating layer and a light emitting element electrically connected to the semiconductor pattern through the first connection electrode and the second connection electrode.

15. The display device of claim 14, wherein the first connection electrode and the first conductive pattern include a same material.

16. The display device of claim 1, wherein a non-conductive film (NCF) is disposed between the driving chip and the pads.

17. The display device of claim 16, wherein the driving chip includes a base film and bumps protruding from the base film and connected to the pads.

18. The display device of claim 1, wherein the pads and the driving chip are curved with a predetermined curvature with respect to the first direction.

19. The display device of claim 1, wherein, in the first direction, a width of the first insulating pattern is in a range of about 5 micrometers (μm) to about 8 μm, and a width of the second insulating pattern is in a range of about 1 μm to about 4 μm.

20. The display device of claim 1, wherein a thickness of the second insulating pattern measured from an uppermost end of the first insulating pattern is 30% or less of a maximum thickness of the first insulating pattern.
